(19) United States
(12) Patent Application Publication
(10) Pub. No.: US 2025/0294907 A1
(43) Pub. Date: Sep. 18, 2025

(54) SEMICONDUCTOR APPARATUS AND METHOD FOR MANUFACTURING SEMICONDUCTOR APPARATUS

(71) Applicant: CANON KABUSHIKI KAISHA, Tokyo (JP)

(72) Inventor: HIROSHI IKAKURA, Kanagawa (JP)

(21) Appl. No.: 19/058,236

(22) Filed: Feb. 20, 2025

(30) Foreign Application Priority Data
Mar. 15, 2024 (JP) 2024-041056

(51) Int. Cl. H10F 39/00; H10F 30/225; H10F 39/10

(52) U.S. Cl. CPC H10F 39/807; H10F 39/011; H10F 39/103; H10F 30/225; H10F 39/811

(57) ABSTRACT

A semiconductor apparatus includes a plurality of photoelectric conversion units, and a pixel isolation portion having a DTI structure that isolates the plurality of photoelectric conversion units from each other. The pixel isolation portion includes a plurality of convex portions protruding inward of a trench of the DTI structure from a side where the photoelectric conversion unit is disposed, and a dielectric arranged inside the trench in contact with the plurality of convex portions. The plurality of convex portions and the dielectric have different refractive indexes with respect to incident light. The plurality of convex portions is formed of poly-silicon.

### BACKGROUND OF THE INVENTION

### Field of the Invention

The present invention relates to an improvement in sensitivity of a photoelectric conversion apparatus that is a semiconductor apparatus.

### Description of the Related Art

JP 2021-197401 A discloses a solid-state image pickup element including an inter-pixel isolation portion having a protrusion protruding toward a photoelectric conversion unit. Furthermore, J P 2021-197401 A discloses deep trench isolation (hereinafter referred to as DTI) as an example of a pixel isolation portion.

In addition, US 2013/0307040 A1 discloses an example in which poly-Si is used for a DTI portion.

The DTI disclosed in JP 2021-197401 A may not be always optimal from the viewpoint of sensitivity to incident light in a photoelectric conversion apparatus.

Therefore, a technique for improving a photoelectric conversion apparatus having DTI in terms of sensitivity has been expected.

### SUMMARY OF THE INVENTION

According to a first aspect of the present invention, a semiconductor apparatus includes a plurality of photoelectric conversion units, and a pixel isolation portion having a DTI structure that isolates the plurality of photoelectric conversion units from each other. The pixel isolation portion includes a plurality of convex portions protruding inward of a trench of the DTI structure from a side where the photoelectric conversion unit is disposed, and a dielectric arranged inside the trench in contact with the plurality of convex portions. The plurality of convex portions and the dielectric have different refractive indexes with respect to incident light. The plurality of convex portions is formed of poly-silicon.

According to a second aspect of the present invention, a method for manufacturing a semiconductor apparatus includes forming a plurality of photoelectric conversion units on a semiconductor substrate, and forming a pixel isolation portion having a DTI structure that isolates the plurality of photoelectric conversion units from each other. The forming of the pixel isolation portion includes forming a trench between the plurality of photoelectric conversion units, forming, from poly-silicon, a plurality of convex portions protruding inward of the trench from a side surface of the trench, and arranging a dielectric inside the trench in contact with the plurality of convex portions. The plurality of convex portions is formed of a material having a refractive index with respect to incident light different from the refractive index of the dielectric.

Further features of the present invention will become apparent from the following description of exemplary embodiments with reference to the attached drawings.

### BRIEF DESCRIPTION OF THE DRAWINGS

FIG. 1 is a schematic cross-sectional view illustrating across section of apart of a photoelectric conversion apparatus according to a first embodiment cut in a direction perpendicular to a light receiving surface of a photoelectric conversion element 100.

FIG. 2 is a schematic cross-sectional view for explaining that a pixel isolation portion of the photoelectric conversion apparatus according to the embodiment has a function of scattering incident light obliquely.

FIG. 3 is a schematic view illustrating a surface of a trench of a first pixel isolation portion.

FIG. 4A is a schematic view illustrating an example of across section obtained by cutting the first pixel isolation portion.

FIG. 4B is a schematic view illustrating another example of across section obtained by cutting the first pixel isolation portion.

FIG. 5 is a schematic view illustrating a modification of a surface of a trench of the first pixel isolation portion.

FIG. 6 is a schematic view illustrating across section taken along line A-A′ of FIG. 5.

FIG. 7 is a schematic plan view of a light receiving surface to illustrate an example in which the first pixel isolation portion is disposed.

FIG. 8 is a schematic plan view of a light receiving surface to illustrate another example in which the first pixel isolation portion is disposed.

FIG. 9 is a schematic partial cross-sectional view illustrating a sensor substrate before the first pixel isolation portion is formed.

FIG. 10 is a schematic partial cross-sectional view illustrating a step in which a trench for the first pixel isolation portion is formed.

FIG. 11 is a schematic partial cross-sectional view illustrating a step in which an impurity layer to be a second P-type semiconductor region is formed.

FIG. 12 is a schematic partial cross-sectional view illustrating a step in which an HSG-Si layer is formed on an inner surface of the trench.

FIG. 13 is a schematic partial cross-sectional view illustrating a step in which a second dielectric layer is deposited in the trench.

FIG. 14 is a schematic partial cross-sectional view illustrating a step in which a layer deposited on the sensor substrate is removed.

FIG. 15 is a schematic partial cross-sectional view illustrating a step in which a first P-type semiconductor region, a second N-type semiconductor region, and a first N-type semiconductor region are formed.

FIG. 16 is a schematic partial cross-sectional view illustrating a step in which an interlayer insulating film, a substrate connecting plug, and a metal wiring are formed.

FIG. 17 is a schematic partial cross-sectional view illustrating a circuit substrate on which a semiconductor element is formed.

FIG. 18 is a schematic partial cross-sectional view illustrating a step in which the sensor substrate and the circuit substrate are bonded and joined.

FIG. 19 is a schematic partial cross-sectional view illustrating a step in which the sensor substrate is thinned and a third P-type semiconductor region is formed.

FIG. 20 is a schematic partial cross-sectional view illustrating a step in which alight shielding layer, a passivation layer, and an inner lens are formed.

FIG. 21 is a schematic partial cross-sectional view illustrating a step in which a sensor substrate and a circuit substrate are bonded and joined in a second embodiment.

FIG. 22 is a schematic partial cross-sectional view illustrating a step in which a trench for creating a second pixel isolation portion is formed on a light incident surface.

FIG. 23 is a schematic partial cross-sectional view illustrating a step in which a pinning film is deposited around the trench, and a dielectric is deposited in the trench and on an upper surface around the trench.

FIG. 24 is a schematic partial cross-sectional view illustrating a step in which alight shielding layer, a passivation layer, and an inner lens that shield the second pixel isolation portion are formed.

FIG. 25A is a schematic view for explaining equipment according to a third embodiment.

FIG. 25B is a schematic view illustrating an example of a photoelectric conversion system according to the third embodiment.

FIG. 25C is a schematic view illustrating an example of an in-vehicle photoelectric conversion system according to the third embodiment.

### DESCRIPTION OF THE EMBODIMENTS

A photoelectric conversion apparatus according to an embodiment of the present invention will be described with reference to the drawings. The embodiments to be described below are exemplary, and for example, detailed configurations can be appropriately modified for implementation by those skilled in the art without departing from the gist of the present invention.

Meanwhile, it should be noted that, in the drawings referred to in the following description of embodiments, elements denoted by the same reference numerals have the same functions unless otherwise specified. In the drawings, in a case where a plurality of identical elements is arranged, the reference numerals and explanations thereof may be omitted.

In addition, since the drawings may be schematically represented for convenience of illustration and description, shapes, sizes, arrangements, and the like of elements illustrated in the drawings may not be exactly consistent with actual objects. In addition, “XX or more and YY or less” or “XX to YY” indicating a numerical range means a numerical range including end points XX (lower limit) and YY(upper limit) unless otherwise specified. When numerical ranges are described in stages, the upper limits and the lower limits of the respective numerical ranges can be combined in any manner.

### First Embodiment

### Structure of Photoelectric Conversion Apparatus

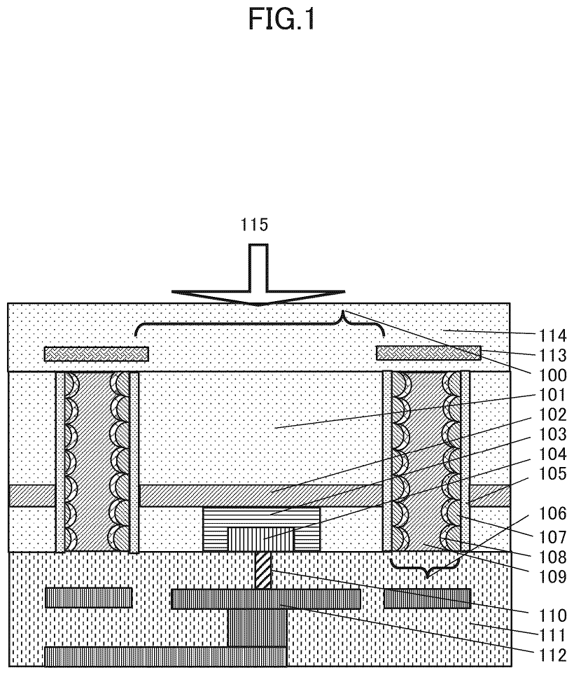

A structure of a photoelectric conversion apparatus according to a first embodiment will be described with reference to the drawings. FIG. 1 is a schematic cross-sectional view illustrating a cross section of a part of a photoelectric conversion apparatus according to the first embodiment cut in a direction perpendicular to a light receiving surface of a photoelectric conversion element 100. The photoelectric conversion apparatus includes a plurality of photoelectric conversion elements 100, and FIG. 1 illustrates the vicinity of one element among them. The photoelectric conversion elements 100 are separated from each other by a first pixel isolation portion 106.

The photoelectric conversion element 100 includes an N-type semiconductor 101 functioning as a photoelectric conversion region, a first P-type semiconductor region 102, a second N-type semiconductor region 103, a first N-type semiconductor region 104, a second P-type semiconductor region 105, and the like, and is formed in a Si single crystal layer.

The first pixel isolation portion 106 includes a hemi-spherical-grained-poly-Si layer (HSG-Si layer) 107, a first dielectric layer 108, which is a pinning layer, and a second dielectric layer 109. The HSG-Si layer 107 refers to a poly-Si layer having hemispherical grain protrusions, but as will be described below, the shape of the convex portions of the HSG-Si layer 107 is not necessarily hemispherical.

In this example, the pinning layer is made of a dielectric, but may not be disposed, for example, if it can be substituted with the characteristic of the second P-type semiconductor region 105. The photoelectric conversion element 100 and the first pixel isolation portion 106 are disposed on a substrate connecting plug 110 and a metal wiring 112 with an interlayer insulating film 111 interposed therebetween.

Furthermore, on the side where incident light 115 is incident, a light shielding layer 113 is disposed above the first pixel isolation portion 106. The photoelectric conversion element 100 and the first pixel isolation portion 106 are protected from an external environment by a passivation layer 114. In FIG. 1, the incident light 115 is illustrated as being incident perpendicularly to the light receiving surface, but in reality, the incident light 115 may be incident from a direction that is not perpendicular to the light receiving surface.

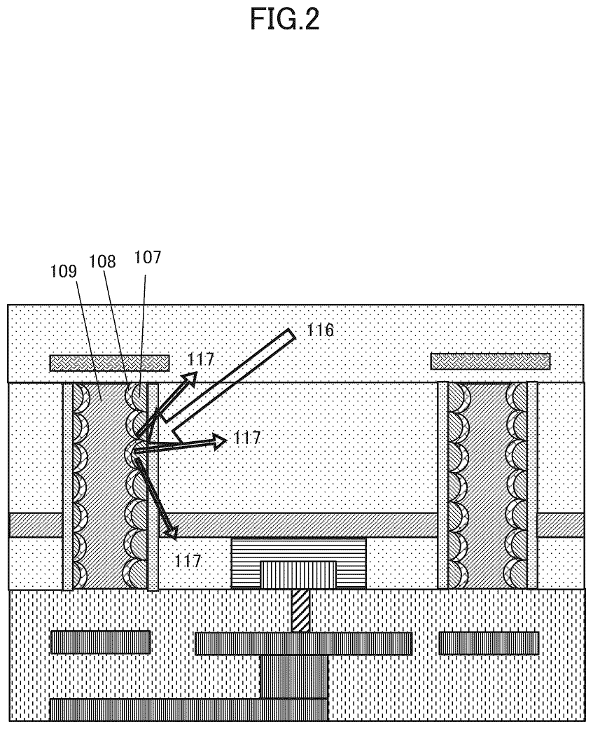

FIG. 2 is a schematic cross-sectional view for explaining that the pixel isolation portion of the photoelectric conversion apparatus according to the present embodiment has a function of scattering incident light incident obliquely. In FIG. 2, incident light 116 is incident at an angle from a side where the photoelectric conversion unit is disposed, but the incident light 116 is incident on a boundary between the HSG-Si layer 107, the first dielectric layer 108, and the second dielectric layer 109 of the first pixel isolation portion 106. Since the HSG-Si layer 107 and the first dielectric layer 108, which is a pinning layer, have a large difference in refractive index, the incident light 116 is scattered at this interface as illustrated in FIG. 2. In a case where there is no first dielectric layer 108 as a pinning layer, the incident light 116 is scattered at a boundary between the HSG-Si layer 107 and the second dielectric layer 109. In the present embodiment, since the HSG-Si layer 107 is formed with projections and recesses randomly arranged from its formation process, there is no regularity in the scattering direction of scattered light 117, and the scattered light is not biased in a certain direction, and is homogenized from a macroscopic perspective and scattered in all directions.

Here, in a case where the incident light is visible light, for example, when the main component of the first dielectric layer 108, which is a pinning layer, is Al₂O₃, the refractive index with respect to the incident light is 1.6. When the main component of the second dielectric layer 109 is a silicon dioxide film, the refractive index thereof is 1.46. The HSG-Si layer 107 is formed of a poly-Si material and has a refractive index of about 4.0. The refractive index of the plurality of convex portions (HSG-Si layer) with respect to incident light is preferably 2.0 or more higher than the refractive index of the dielectric abutting on the plurality of convex portions on a side opposite to the photoelectric conversion unit.

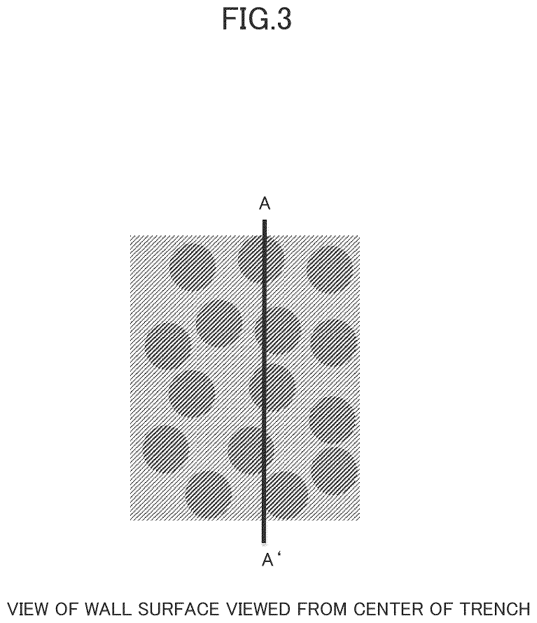

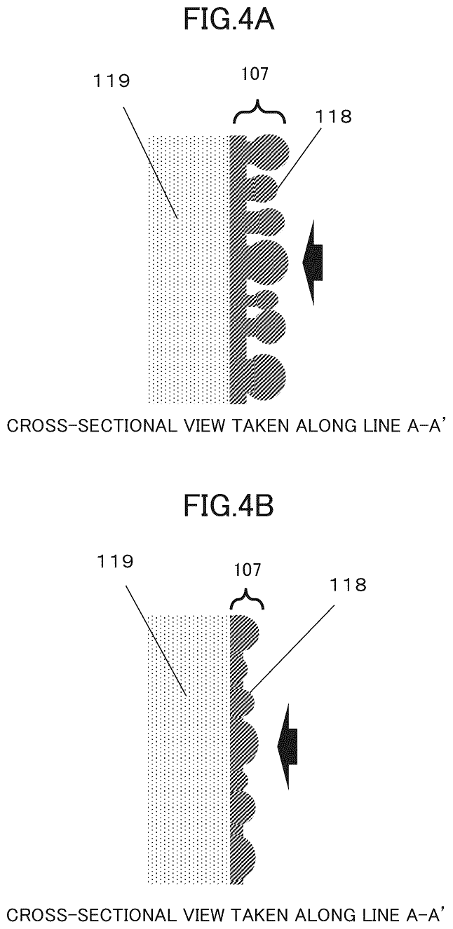

FIG. 3 is a schematic view illustrating a surface of a trench of the first pixel isolation portion 106. FIG. 3 is a view of a wall surface viewed from the center of a trench, and is a view of the wall surface viewed from a direction of an arrow shown in FIGS. 4A and 4B to be described below. As illustrated in FIG. 3, in the HSG-Si layer 107, grain protrusions having substantially the same size due to its characteristics are randomly distributed without regularity with respect to the wall surface.

FIGS. 4A and 4B are schematic views illustrating a cross section of the first pixel isolation portion 106 taken along line A-A′ illustrated in FIG. 3. In the HSG-Si layer 107 deposited on a surface (side surface) of a single crystal region of the photoelectric conversion unit 119, mushroom-shaped convex portions 118 illustrated in FIG. 4A and hemispherical convex portions 118 illustrated in FIG. 4B are formed depending on the conditions of the formation process. The HSG-Si layer 107 is made of poly-Si, and is polycrystalline. When the crystal structure of the cross section is observed by TEM or the like, a boundary between a Si single crystal layer constituting the photoelectric conversion unit 119 and a Si polycrystal layer constituting the HSG-Si layer 107 can be seen.

The deep trench of the first pixel isolation portion 106 is opened using a dry etching method, and is often formed using a repetitive process called a Bosch method. At this time, projections and recesses perpendicular to the depth direction (parallel to the incident light surface) may be repeatedly and periodically formed along the depth direction in the trench. In this case, a trench side surface 120 of the single crystal region constituting the photoelectric conversion unit 119 is processed into a wavy shape.

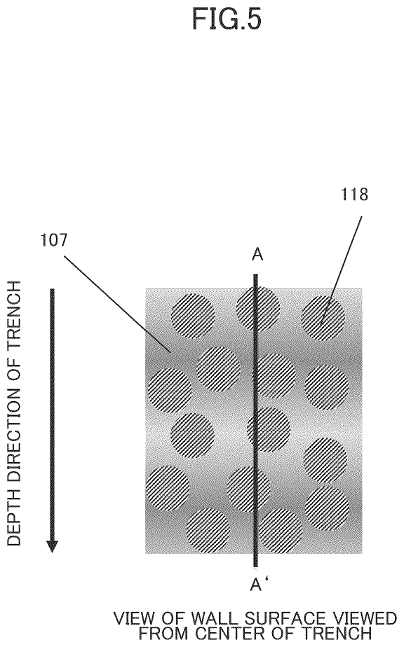

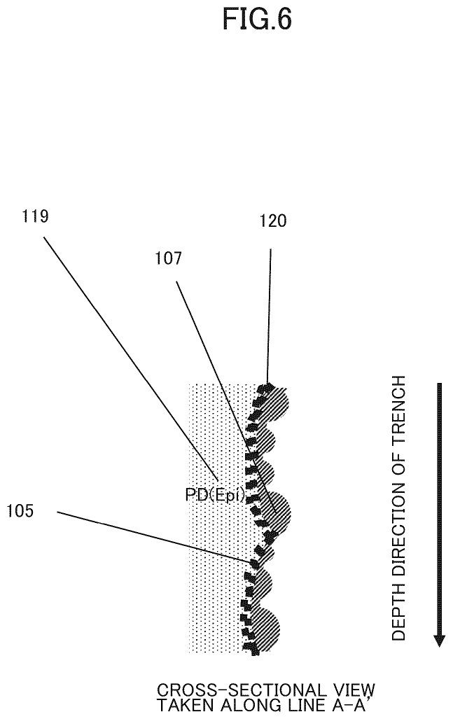

Then, the convex portions 118 that are grain protrusions of the HSG-Si layer 107 are formed in a distributed manner on the processed surface that periodically and repeatedly undulates in the depth direction. When the pixel isolation portion is observed from the light incident surface, the width of the isolation portion in the depth direction appears to periodically increase or decrease depending on the depth. FIG. 5 is a schematic view of the surface of the trench in the first pixel isolation portion 106 illustrating this state, and FIG. 6 is a schematic view illustrating a cross section taken along line A-A′ of FIG. 5. The convex portions of the HSG-Si layer 107 are not concentrated on a part of an inner surface of the trench, and the convex portions having similar sizes are irregularly (randomly) distributed in the depth direction and the circumferential direction of the trench.

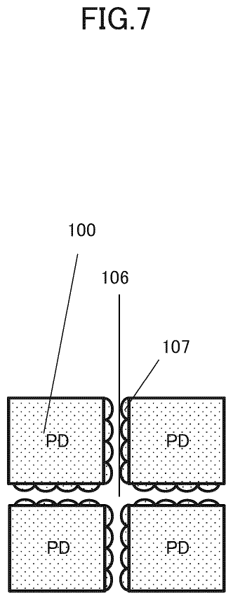

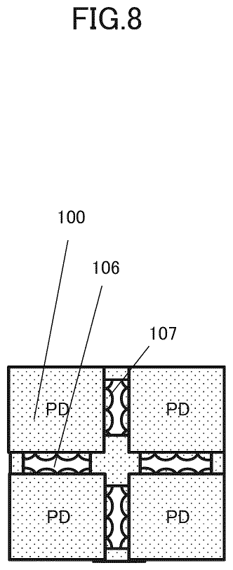

FIGS. 7 and 8 are schematic views of light receiving surfaces in plan view from the direction in which the incident light 115 is incident, and illustrate different arrangements of the first pixel isolation portions 106 that isolate the photoelectric conversion elements 100. The first pixel isolation portion 106 may be formed in a lattice shape so as to surround the periphery of each photoelectric conversion element 100 as illustrated in FIG. 7, or may be formed along a part of each photoelectric conversion element 100 as illustrated in FIG. 8.

As described above, the photoelectric conversion apparatus according to the present embodiment includes DTI for isolating pixels from each other, and an interface is formed between materials having different refractive indexes inside the DTI, and irregular protrusions and recesses are formed as a shape of the interface. In this manner, since the scattering surface is formed inside the DTI, light incident on the DTI is scattered and reaches the photoelectric conversion region of the pixel. Therefore, the photoelectric conversion apparatus according to the present embodiment can achieve high sensitivity.

The semiconductor apparatus according to the present embodiment has the following features. The semiconductor apparatus includes a plurality of photoelectric conversion units, and a pixel isolation portion having a DTI structure that isolates the plurality of photoelectric conversion units from each other. The pixel isolation portion includes a plurality of convex portions protruding inward of a trench of the DTI structure from a side where the photoelectric conversion unit is disposed, and a dielectric arranged inside the trench in contact with the plurality of convex portions. The plurality of convex portions and the dielectric have different refractive indexes with respect to incident light.

Preferably, a material forming the plurality of convex portions has a refractive index with respect to incident light larger than the refractive index of the dielectric. At least a part of the incident light obliquely incident on the pixel isolation portion from the photoelectric conversion unit is scattered at a boundary between the plurality of convex portions and the dielectric and directed to the photoelectric conversion unit.

Preferably, the plurality of convex portions is formed of, for example, poly-silicon. Preferably, a surface on a side where the photoelectric conversion unit is disposed of a layer in which the plurality of convex portions is arranged has higher smoothness as compared to a surface of the plurality of convex portions. Preferably, the dielectric contains either Al₂O₃ or silicon dioxide as a main component.

Preferably, the plurality of convex portions includes at least one hemispherical convex portion or at least one mushroom-shaped convex portion. However, as long as incident light obliquely incident on the DTI from the side where the photoelectric conversion unit is disposed can be scattered and efficiently returned to the photoelectric conversion unit, the plurality of convex portions may have other shapes. Preferably, the plurality of convex portions is irregularly arranged along an inner surface of the trench.

The pixel isolation portion may be arranged to surround the periphery of each of the plurality of photoelectric conversion units. Alternatively, the pixel isolation portion may be disposed along a part of each of the plurality of photoelectric conversion units. Each of the plurality of photoelectric conversion units may include a photodiode, and the photodiode may be an avalanche photodiode.

### Method for Manufacturing Photoelectric Conversion Apparatus

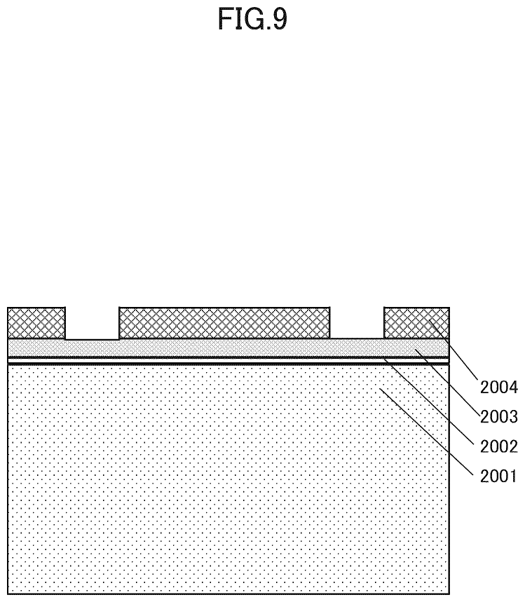

A method for manufacturing a photoelectric conversion apparatus according to the present embodiment will be described with reference to schematic partial cross-sectional views illustrated in FIGS. 9 to 20. First, a method for forming a sensor substrate including a photoelectric conversion element will be described with reference to FIGS. 9 to 16.

A sensor substrate 2001 illustrated in FIG. 9 is a single crystal silicon substrate or a silicon substrate having an epitaxial layer. An oxide film 2002 and a nitride film 2003 are patterned by a dry etching method using a photoresist mask 2004 to form a hard mask layer.

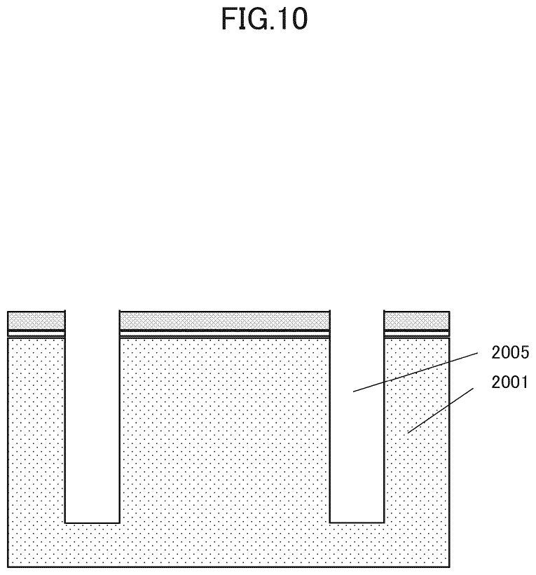

Next, as illustrated in FIG. 10, a pixel isolation portion is patterned by a photolithography method using a hard mask formed by the oxide film 2002 and the nitride film 2003. That is, a trench 2005 for the first pixel isolation portion 106 is formed by a dry etching method using a process condition such as a Bosch method.

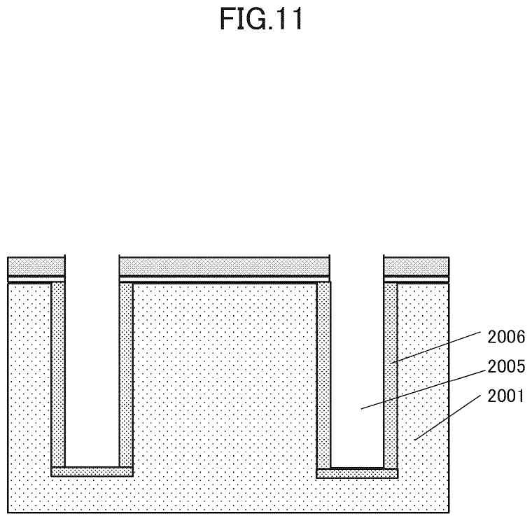

Next, as illustrated in FIG. 11, an impurity layer 2006 to be the second P-type semiconductor region 105 is formed on a side surface of the trench 2005 by using a method such as an ion implantation method, a plasma doping method, or a solid-phase diffusion method. However, the doping of the sensor substrate 2001 with impurities does not need to be performed at this stage, and may be performed in a later process.

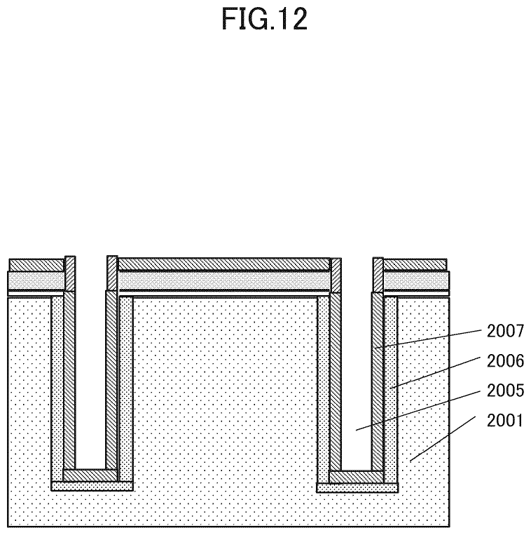

Next, as illustrated in FIG. 12, an HSG-Si layer 2007 to be the HSG-Si layer 107 is formed on an inner surface of the trench 2005. For example, the HSG-Si layer 2007 can be formed as follows. First, an amorphous silicon layer is deposited to have a thickness of 100 nm to 300 nm on the inner surface of the trench 2005 under the process temperature condition of, for example, of 590° C. Then, the surface of the amorphous silicon layer is subjected to an HF cleaning process to remove a natural oxide film, thereby making the surface clean. Thereafter, a Si nucleation process is performed, and a heat treatment is further performed at a temperature of 580° C. to 700° C. for about several seconds to several hundred seconds. At this time, the shape, size, and density of grains (convex portions) of the HSG-Si layer 2007 can be adjusted depending on the conditions such as the heat treatment temperature and the heat treatment time of the nucleation process. For example, the size of the grains (the height of the convex portion) may be larger than 3 nm and smaller than 300 nm.

As simply mentioned in the description regarding FIG. 11, after the formation of the HSG-Si layer 2007, the impurity layer 2006 to be the second P-type semiconductor region 105 may be formed on a single crystal wall surface of the trench 2005 by using an ion implantation method, a solid-phase diffusion method, a plasma doping method, or the like.

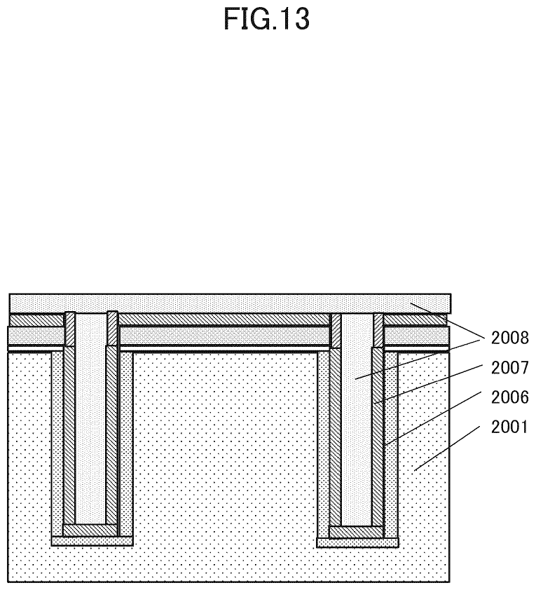

Next, as illustrated in FIG. 13, a dielectric layer 2008 to be the second dielectric layer 109 is deposed in the trench 2005, where the HSG-Si layer 2007 is formed, to form a pixel isolation structure. The dielectric layer 2008 may be formed of a plurality of layers, and is made of any of Al₂O₃, SiO₂, Ta₂O₅, TiN, SiN, SiON, and the like.

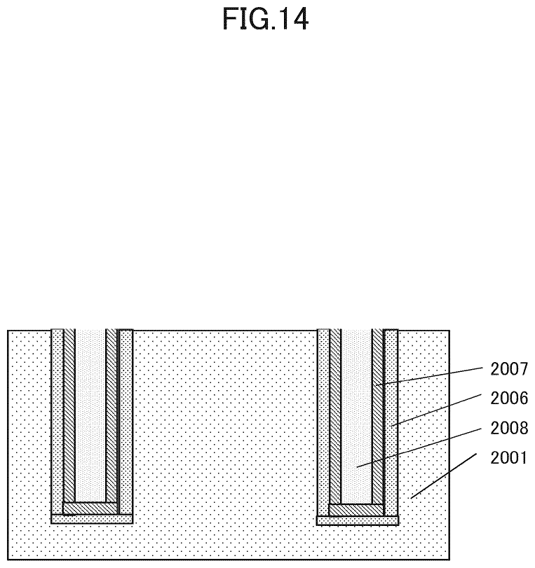

Next, as illustrated in FIG. 14, the layers deposited on the sensor substrate 2001 is removed by a method such as a dry etch-back method, a wet etching method, or a CMP method.

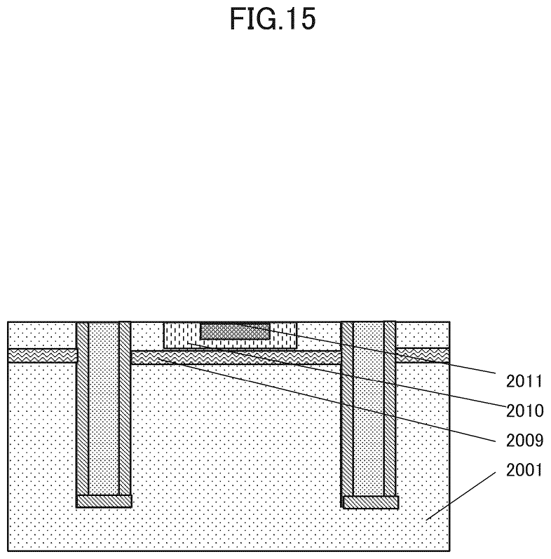

Next, as illustrated in FIG. 15, a region 2009 to be the first P-type semiconductor region 102, a region 2010 to be the second N-type semiconductor region 103, a region 2011 to be the first N-type semiconductor region 104, and the like of the pixel region are formed. These regions can be formed by forming a photoresist mask by a photography method and using an ion implantation method or the like. Alternatively, these regions may be formed using another method, for example, a method such as poly deposition, poly etching, thermal oxidation, CVD, or ALD.

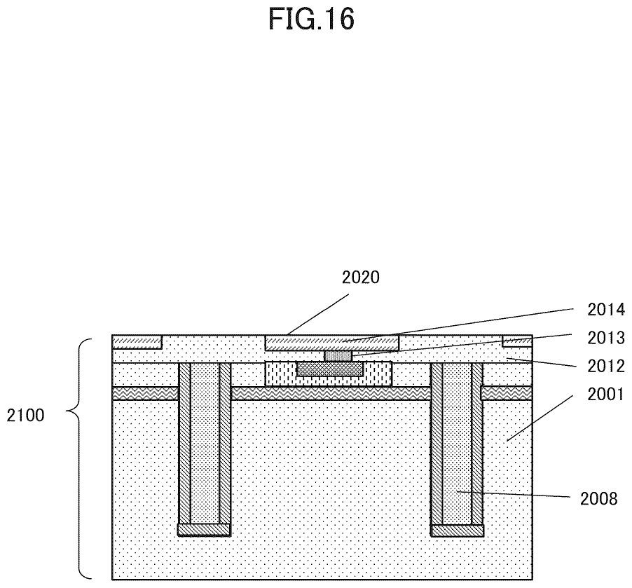

Furthermore, as illustrated in FIG. 16, an insulating film 2012 to be the interlayer insulating film 111, a plug 2013 to be the substrate connecting plug 110, a wiring layer 2014 to be the metal wiring 112, and the like are formed to constitute a sensor substrate 2100 on which a semiconductor element is formed. A plurality of stack structures each including the insulating film 2012 and the wiring layer 2014 may be layered. The insulating film 2012 may be made of SiO₂, SiON, SiN, a low-K film, or the like, and the plug 2013 or the wiring layer 2014 may be made of a material such as AL, Cu, W, or Co. The uppermost surface of the wiring layer serves as a bonding surface 2020 on the sensor substrate side as will be described below.

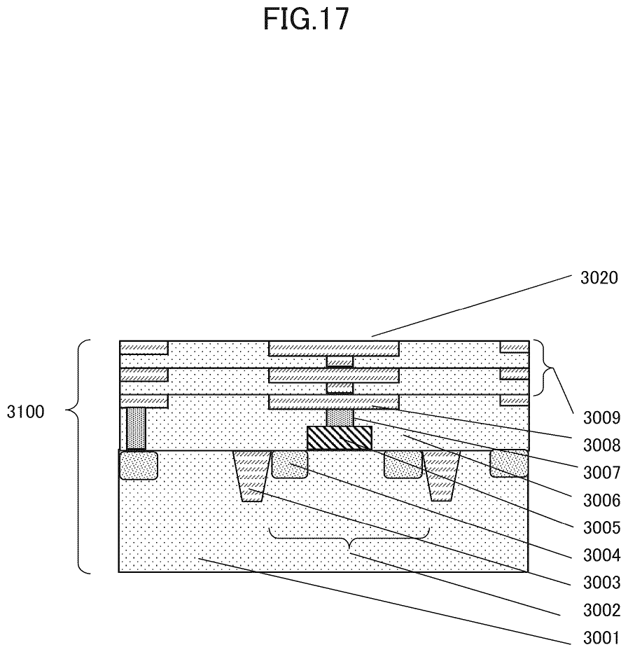

FIG. 17 illustrates a circuit substrate 3100 on which a semiconductor element is formed. The circuit substrate 3100 may be formed using a process similar to that of forming the sensor substrate, or may be formed using another method. The circuit substrate 3100 on which the semiconductor element is formed includes a semiconductor substrate 3001 and a wiring structure.

In the semiconductor substrate 3001, a transistor 3002 including a first element isolation portion 3003, a source/drain region 3004, a poly-Si gate 3005, and the like are formed by combining a photolithography method and an ion implantation method.

The wiring structure includes a substrate connecting plug 3007, and a multilayer metal wiring layer 3009 including an interlayer insulating film 3006 and a plurality of metal wirings 3008, and the like. The uppermost surface of the wiring layer serves as a bonding surface 3020 on the circuit substrate side as will be described below.

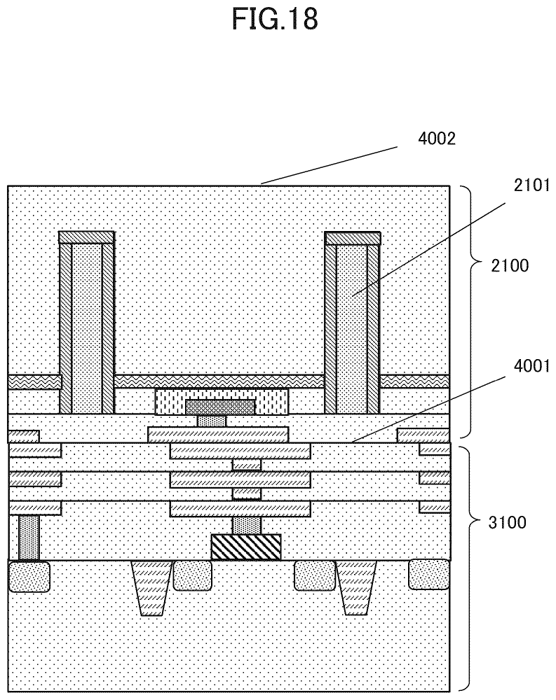

When the sensor substrate 2100 and the circuit substrate 3100 are prepared, they are bonded and joined. FIG. 18 is a schematic view illustrating a state in which the sensor substrate 2100 on which the semiconductor element is formed and the circuit substrate 3100 on which the semiconductor element is formed are bonded together. In the sensor substrate 2100, a portion 2101 to be the first pixel isolation portion 106 is formed.

A bonding surface 2020 on the sensor substrate side and a bonding surface 3020 on the circuit substrate side are bonded to each other on a bonding surface 4001 as illustrated. The bonding surface 2020 and the bonding surface 3020 are aligned and bonded such that the insulating films are bonded to each other and the metal films are bonded to each other, thereby establishing electrical conduction between the sensor substrate 2100 and the circuit substrate 3100. The circuit substrate 3100 serves as a support substrate.

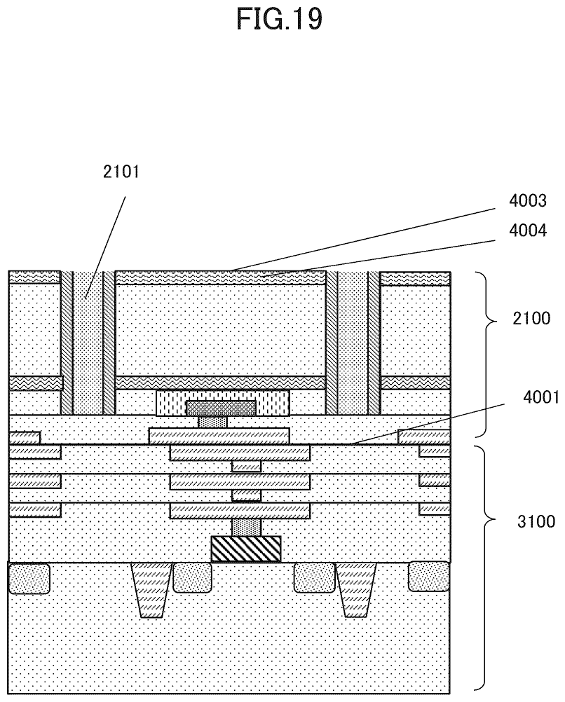

Next, in order to make the photoelectric conversion region function, a back surface of the sensor substrate 2100 is thinned. The thickness of the sensor substrate is preferably, for example, about 300 nm to 5000 nm. Since the thinned surface of the sensor substrate causes dark current, after the surface of the sensor substrate is thinned, a third P-type semiconductor region 4004 may be formed using a plasma doping method or an ion implantation method as illustrated in FIG. 19. As another method, the third P-type semiconductor region 4004 can be allowed to function effectively by depositing a pinning layer. In particular, in a case where the ion implantation method is used, before bonding is performed, ion implantation may be applied in advance to the depth at which the third P-type semiconductor region 4004 is to be formed. Note that FIG. 19 illustrates a structure in a case where the thickness of the sensor substrate 2100 is reduced to be smaller than the depth of the previously formed portion 2101.

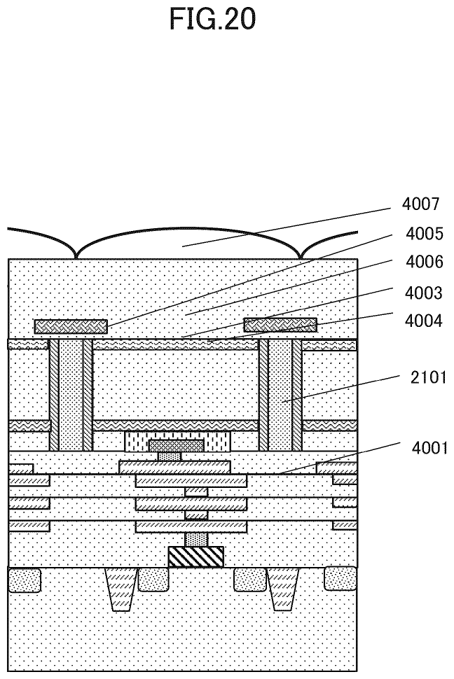

Furthermore, as illustrated in FIG. 20, a layer 4005 to be the light shielding layer 113 that shields the first pixel isolation portion 106, a layer 4006 to be the passivation layer 114, an inner lens 4007, and the like are formed above a light incident surface 4003, thereby completing a photoelectric conversion apparatus.

The method for manufacturing a semiconductor apparatus according to the present embodiment has the following features. A method for manufacturing a semiconductor apparatus includes: forming a plurality of photoelectric conversion units on a semiconductor substrate; and forming a pixel isolation portion having a DTI structure that isolates the plurality of photoelectric conversion units from each other. The forming of the pixel isolation portion includes forming a trench between the plurality of photoelectric conversion units, forming a plurality of convex portions protruding inward of the trench from a side surface of the trench, and arranging a dielectric inside the trench in contact with the plurality of convex portions. A material having a refractive index with respect to incident light different from the refractive index of the dielectric is used for the plurality of convex portions.

Preferably, a material having a refractive index with respect to incident light larger than the refractive index of the dielectric is used as the material forming the plurality of convex portions. Preferably, the plurality of convex portions is formed of poly-silicon. Preferably, a surface on a side where the photoelectric conversion unit is disposed of a layer in which the plurality of convex portions is arranged has higher smoothness as compared to a surface of the plurality of convex portions.

Preferably, in the forming of the plurality of convex portions, after an amorphous silicon layer is formed on an inner surface of the trench, a Si nucleation process and a heat treatment are performed. Preferably, the dielectric is formed of either Al₂O₃ or silicon dioxide as a main component. Preferably, the plurality of convex portions formed includes at least one hemispherical convex portion or at least one mushroom-shaped convex portion. Preferably, the plurality of convex portions is irregularly arranged along the inner surface of the trench.

### Second Embodiment

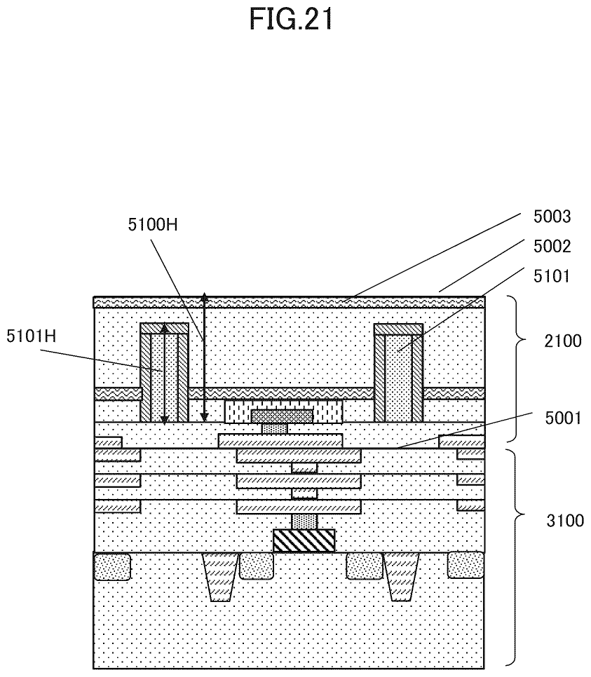

A second embodiment will be described with reference to schematic partial cross-sectional views of FIGS. 21 to 24. The description of matters common to the first embodiment will be simplified or omitted. The photoelectric conversion apparatus according to the present embodiment includes DTI for isolating pixels from each other, and an interface is formed between materials having different refractive indexes inside the DTI, and irregular protrusions and recesses are formed as a shape of the interface. In this manner, since the scattering surface is formed inside the DTI, light incident on the DTI is scattered and reaches the photoelectric conversion region of the pixel. Therefore, the photoelectric conversion apparatus according to the present embodiment can achieve high sensitivity.

In a method for manufacturing a semiconductor apparatus according to the present embodiment, steps are performed by a process similar to that in the first embodiment until the sensor substrate 2100 is thinned after bonding the sensor substrate 2100 on which the semiconductor element is formed and the circuit substrate 3100 on which the semiconductor element is formed.

However, FIG. 19 referred to in the description of the first embodiment illustrates a case where the thickness of the sensor substrate 2100 after being thinned is reduced to be smaller than the depth of the previously formed portion 2101, but the present embodiment is different therefrom.

As illustrated in FIG. 21, in the present embodiment, the sensor substrate 2100 on which the semiconductor element is formed and the circuit substrate 3100 on which the semiconductor element is formed are bonded to each other on a bonding surface 5001. They are aligned and bonded such that the insulating films are bonded to each other and the metal films are bonded to each other, thereby establishing electrical conduction between the sensor substrate 2100 and the circuit substrate 3100.

In the sensor substrate 2100, a portion 5101 to be the first pixel isolation portion 106 is formed, and light is incident on the photoelectric conversion unit from a light incident surface 5002. Similarly to the first embodiment, a third P-type semiconductor region 5003 may be manufactured by forming a P-type region on the surface of the sensor substrate 2100 by plasma doping or ion implantation after thinning the sensor substrate 2100. Alternatively, the third P-type semiconductor region 5003 may be manufactured by forming a P-type region at a depth at which the third P-type semiconductor region 5003 is to be formed before being thinned.

FIG. 21 illustrates a step similar to FIG. 19 in the first embodiment, but is different from the first embodiment in that a thickness 5100H of the sensor substrate after being thinned is larger than a thickness 5101H of the portion 5101 to be the first pixel isolation portion 106.

In the portion 5101 to be the first pixel isolation portion 106, a surface (an upper surface in FIG. 21) opposite to the circuit substrate 3100 is at a position lower than the light incident surface 5002. For this reason, there is a possibility that incident light leaks from a gap between the light incident surface 5002 and the portion 5101 to be the pixel isolation portion to a photoelectric conversion unit of an adjacent pixel, for example, causing color mixture.

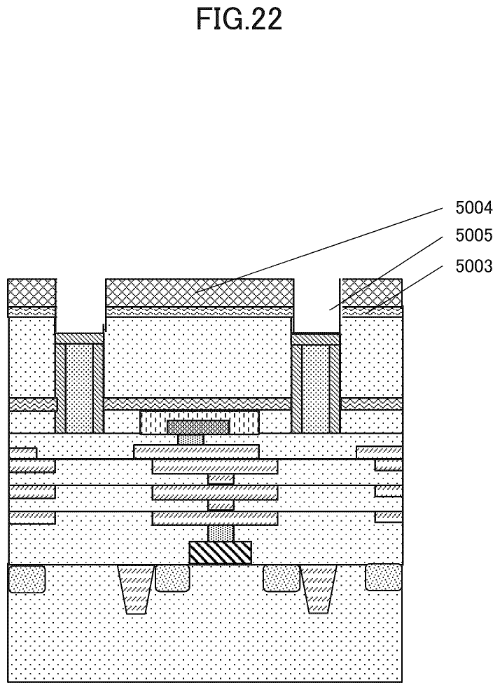

Therefore, in the present embodiment, as illustrated in FIG. 22, a trench 5005 for creating a second pixel isolation portion is formed on the light incident surface side using a photoresist mask 5004 and a dry etching method.

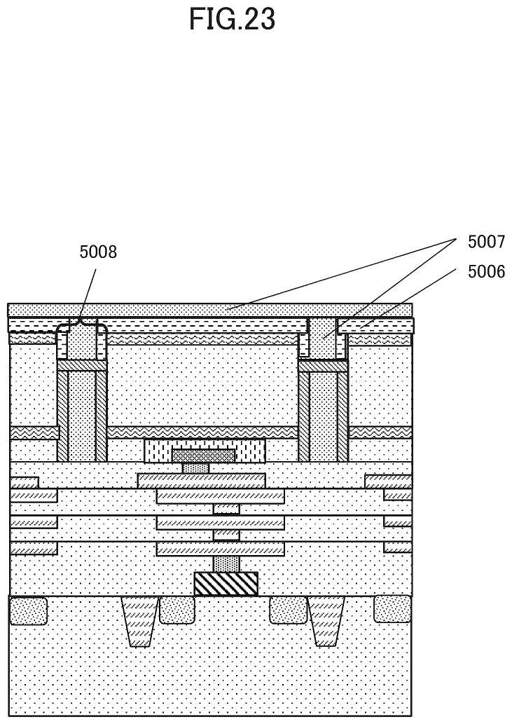

Furthermore, as illustrated in FIG. 23, a pinning film 5006 made of, for example, Al₂O₃ may be deposited around the trench 5005, or TiN, Ta₂O₅, SiN, SiON, SiO₂, or the like may be deposited as another dielectric. Further, a dielectric 5007 is deposited in the trench 5005 and on an upper surface around the trench 5005. As a material of the dielectric 5007, SIO, SIN, SION, or the like can be used. In this way, a second pixel isolation portion 5008 is formed.

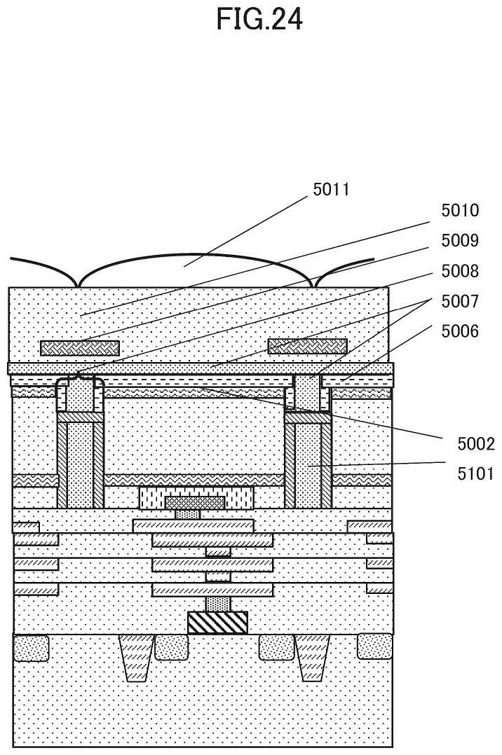

Furthermore, as illustrated in FIG. 24, a layer 5009 to be the light shielding layer 113 that shields the second pixel isolation portion 5008, a layer 5010 to be the passivation layer 114, an inner lens 5011, and the like are formed above the light incident surface 5002, thereby completing a photoelectric conversion apparatus.

### Third Embodiment

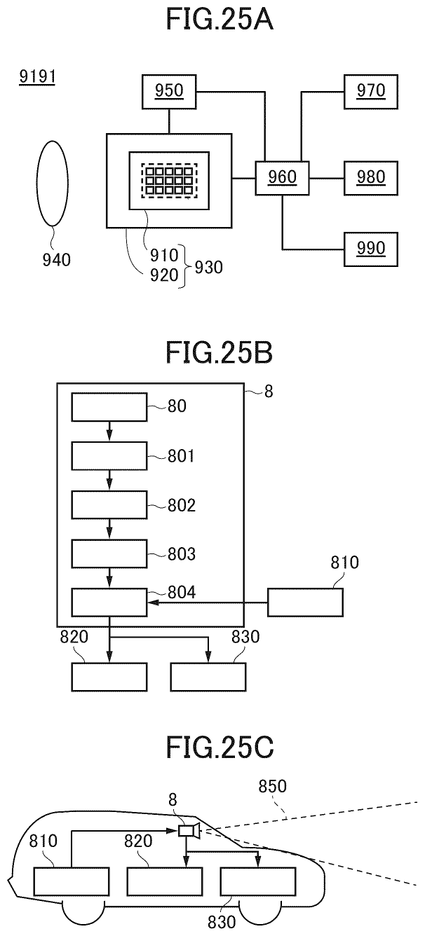

As a third embodiment, equipment including the semiconductor apparatus (solid-state image pickup apparatus) according to any one of the above-described embodiments will be described. FIG. 25A is a schematic view for explaining equipment 9191 including a semiconductor apparatus 930 according to the above-described embodiment. The equipment 9191 including the semiconductor apparatus 930 will be described in detail.

The semiconductor apparatus 930 includes a semiconductor device 910 in which a first chip serving as a photoelectric conversion apparatus and a second chip including at least one of a memory circuit and a logic circuit are integrated. In addition to the semiconductor device 910, the semiconductor apparatus 930 may include a package 920 that houses the semiconductor device 910. The package 920 may include abase to which the semiconductor device 910 is secured and a lid, such as glass, opposite the semiconductor device 910. The package 920 may further include a bonding member such as a bonding wire or a bump that connects a terminal provided on the base and a terminal provided on the semiconductor device 910.

The equipment 9191 may include at least one of an optical device 940, a control device 950, a processing device 960, a display device 970, a storage device 980, and a mechanical device 990. The optical device 940 is, for example, a lens, a shutter, or a mirror provided to correspond to the semiconductor apparatus 930. The control device 950 controls the semiconductor apparatus 930. The control device 950 is, for example, a semiconductor apparatus such as an ASIC.

The processing device 960 processes a signal output from the semiconductor apparatus 930. The processing device 960 is a semiconductor apparatus such as a CPU or an ASIC for configuring an analog front end (AFE) or a digital front end (DFE). The display device 970 is an EL display device or a liquid crystal display device that displays information (image) obtained by the semiconductor apparatus 930. The storage device 980 is a magnetic device or a semiconductor device that stores information (image) obtained by the semiconductor apparatus 930. The storage device 980 is a volatile memory such as an SRAM or a DRAM, or a nonvolatile memory such as a flash memory or a hard disk drive.

The mechanical device 990 includes a movable unit such as a motor or an engine, or a propulsion unit. A signal output from the semiconductor apparatus 930 is displayed on the display device 970 in the equipment 9191, or is transmitted to the outside by a communication device (not illustrated) included in the equipment 9191. Therefore, it is preferable that the equipment 9191 further includes a storage device 980 and a processing device 960 separately from the storage circuit and the arithmetic circuit included in the semiconductor apparatus 930. The mechanical device 990 may be controlled based on a signal output from the semiconductor apparatus 930.

Furthermore, the equipment 9191 is suitable for electronic equipment such as an information terminal having a photographing function (e.g., a smartphone or a wearable terminal) or a camera (e.g., an interchangeable lens camera, a compact camera, a video camera, or a surveillance camera). The mechanical device 990 in the camera may drive components of the optical device 940 for zooming, focusing, and shutter operations. Alternatively, the mechanical device 990 in the camera may move the semiconductor apparatus 930 for a vibration-proof operation.

Furthermore, the equipment 9191 may be transport equipment such as a vehicle, a ship, or a flying object. The mechanical device 990 in the transport equipment can be used as a moving device. The equipment 9191 serving as transport equipment is suitable for transporting the semiconductor apparatus 930 and assisting and/or automating driving (steering) by using a photographing function. The processing device 960 for assisting and/or automating driving (steering) can perform processing for operating the mechanical device 990 serving as a moving device based on information obtained by the semiconductor apparatus 930. Alternatively, the equipment 9191 may be medical equipment such as an endoscope, measuring equipment such as a distance measuring sensor, analyzing equipment such as an electron microscope, office equipment such as a copying machine, or industrial equipment such as a robot. The photoelectric conversion apparatus according to the above-described embodiment is capable of obtaining high sensitivity, making it possible to stably acquire an image having favorable characteristics.

Therefore, when the semiconductor apparatus 930 according to the present embodiment is used for the equipment 9191, the value of the equipment can also be improved. For example, it is possible to obtain excellent performance when the semiconductor apparatus 930 is mounted on the transport equipment and the outside of the transport equipment is photographed or the external environment is measured. Therefore, in manufacturing and selling the transport equipment, it is advantageous to determine to mount the semiconductor apparatus according to the present embodiment on the transport equipment in order to enhance the performance of the transport equipment itself. In particular, the semiconductor apparatus 930 is suitable for transport equipment that performs driving support and/or automatic driving of the transport equipment using information obtained by the semiconductor apparatus. Note that implementation of the semiconductor apparatus in a vehicle, a ship, a flying body, and the like is not limited to application to equipment practically used for transport purposes, and the semiconductor apparatus can be suitably implemented in, for example, a drone that performs aerial photographing or the like for various purposes including inspecting buildings and agricultural facilities, monitoring natural phenomena, and the like.

A photoelectric conversion system and a mobile body according to the present embodiment will be described with reference to FIGS. 25B and 25C. FIG. 25B illustrates an example of a photoelectric conversion system related to an in-vehicle camera. A photoelectric conversion system 8 includes a photoelectric conversion apparatus 80. The photoelectric conversion apparatus 80 is a photoelectric conversion apparatus serving as an electronic component described in the above-described embodiment. The photoelectric conversion system 8 includes an image processing unit 801 that performs image processing on a plurality of pieces of image data acquired by the photoelectric conversion apparatus 80, and a parallax acquisition unit 802 that calculates a parallax (a phase difference between parallax images) from the plurality of pieces of image data acquired by the photoelectric conversion system 8. Furthermore, the photoelectric conversion system 8 includes a distance acquisition unit 803 that calculates a distance to an object based on the calculated parallax, and a collision determination unit 804 that determines whether there is a possibility of collision based on the calculated distance. Here, the parallax acquisition unit 802 and the distance acquisition unit 803 are an example of a distance information acquisition unit that acquires distance information to the object. That is, the distance information is information regarding parallax, a defocus amount, a distance to an object, and the like. The collision determination unit 804 may determine a collision possibility using any one of these pieces of distance information. The distance information acquisition unit may be realized by dedicated hardware or may be realized by a software module. In addition, the distance information acquisition unit may be realized by a field programmable gate array (FPGA), an application specific integrated circuit (ASIC), or the like.

The photoelectric conversion system 8 is connected to a vehicle information acquisition device 810, and can acquire vehicle information such as a vehicle speed, a yaw rate, and a steering angle. In addition, the photoelectric conversion system 8 is connected to a control ECU 820 that is a control device that outputs a control signal for generating a braking force on the vehicle based on a determination result of the collision determination unit 804. The photoelectric conversion system 8 is also connected to a warning device 830 that issues a warning to a driver based on a determination result of the collision determination unit 804. For example, when the possibility of collision is high as a determination result of the collision determination unit 804, the control ECU 820 performs vehicle control to avoid collision and reduce damage by applying a brake, returning an accelerator, suppressing an engine output, or the like. The warning device 830 gives a warning to a user by giving a sound warning or the like, displaying warning information on a screen of a car navigation system or the like, giving a vibration to a seat belt or a steering wheel, or the like.

In the present embodiment, the periphery of the vehicle, for example, an area in front of or behind the vehicle is imaged by the photoelectric conversion system 8. FIG. 25C illustrates the photoelectric conversion system in a case where the area in front of the vehicle (an image pickup range 850) is imaged. The vehicle information acquisition device 810 sends an instruction to the photoelectric conversion system 8 or the photoelectric conversion apparatus 80. With such a configuration, the distance measurement accuracy can be further improved.

The example of performing control not to collide with another vehicle has been described above, but control may be performed for automatic driving to follow another vehicle, automatic driving to avoid straying from lanes. Furthermore, the photoelectric conversion system can be applied to, for example, a moving object (moving device) such as a ship, an aircraft, or an industrial robot, not limited to a vehicle such as a host vehicle. In addition, the photoelectric conversion system can be applied to equipment that widely uses object recognition, such as an intelligent transport system (ITS), not limited to a moving object. According to the above-described embodiment, it is possible to stably acquire an image having favorable characteristics.

### Modification

Note that the present invention is not limited to the above-described embodiments and examples, and many modifications can be made within the technical spirit of the present invention. For example, all or some of the different embodiments described above may be combined for implementation. According to the present invention, it is possible to provide a technique for improving sensitivity of a photoelectric conversion apparatus having DTI.

The conductivity type of the semiconductor layer described in the embodiment is an example, and is not limited to only the conductivity type described in the embodiment.

The semiconductor apparatus described in each of the embodiments is not limited to a photoelectric conversion apparatus for image pickup purposes. For example, the semiconductor apparatus described in each of the embodiments is also applicable to a distance measuring device (a device for focus detection, distance measurement using a time of flight (TOF), or the like), a photometric device (a device for measuring an amount of incident light, or the like), or the like. The photoelectric conversion apparatus to which the present invention can be applied is not limited to a specific form, and for example, the portion of the image pickup element may be either a front surface irradiation type or a back surface irradiation type. Furthermore, the photoelectric conversion unit included in the image pickup element may be an avalanche photodiode.

### Other Embodiments

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-041056, filed Mar. 15, 2024, which is hereby incorporated by reference herein in its entirety.

What is claimed is:

1. A semiconductor apparatus comprising:
a plurality of photoelectric conversion units; and
a pixel isolation portion having a DTI structure that isolates the plurality of photoelectric conversion units from each other,
wherein the pixel isolation portion includes a plurality of convex portions protruding inward of a trench of the DTI structure from a side where the photoelectric conversion unit is disposed, and a dielectric arranged inside the trench in contact with the plurality of convex portions,
wherein the plurality of convex portions and the dielectric have different refractive indexes with respect to incident light, and
wherein the plurality of convex portions is formed of poly-silicon.

2. The semiconductor apparatus according to claim 1, wherein
a material forming the plurality of convex portions has a refractive index with respect to incident light larger than the refractive index of the dielectric.

3. The semiconductor apparatus according to claim 1, wherein
at least a part of the incident light incident on the pixel isolation portion is scattered at a boundary between the plurality of convex portions and the dielectric and directed to the photoelectric conversion units.

4. The semiconductor apparatus according to claim 1, wherein
a surface on a side where the photoelectric conversion units are disposed of a layer in which the plurality of convex portions is arranged has higher smoothness as compared to a surface of the plurality of convex portions.

5. The semiconductor apparatus according to claim 1, wherein
the dielectric contains either Al₂O₃ or silicon dioxide as a main component.

6. The semiconductor apparatus according to claim 1, wherein
the plurality of convex portions includes at least one hemispherical convex portion or at least one mushroom-shaped convex portion.

7. The semiconductor apparatus according to claim 1, wherein
the plurality of convex portions is irregularly arranged along an inner surface of the trench.

8. The semiconductor apparatus according to claim 1, wherein
the pixel isolation portion is disposed to surround a periphery of each of the plurality of photoelectric conversion units.

9. The semiconductor apparatus according to claim 1, wherein
the pixel isolation portion is disposed along a part of each of the plurality of photoelectric conversion units.

10. The semiconductor apparatus according to claim 1, wherein
each of the plurality of photoelectric conversion units includes a photodiode.

11. The semiconductor apparatus according to claim 10, wherein
the photodiode is an avalanche photodiode.

12. A method for manufacturing a semiconductor apparatus, the method comprising: forming a plurality of photoelectric conversion units on a semiconductor substrate; and forming a pixel isolation portion having a DTI structure that isolates the plurality of photoelectric conversion units from each other,
wherein the forming of the pixel isolation portion includes:
forming a trench between the plurality of photoelectric conversion units;
forming, from poly-silicon, a plurality of convex portions protruding inward of the trench from a side surface of the trench; and
arranging a dielectric inside the trench in contact with the plurality of convex portions, and
wherein the plurality of convex portions is formed of a material having a refractive index with respect to incident light different from the refractive index of the dielectric.

13. The method according to claim 12, wherein
a material having a refractive index with respect to incident light larger than the refractive index of the dielectric is used as the material for forming the plurality of convex portions.

14. The method according to claim 12, wherein
a surface on a side where the photoelectric conversion units are disposed of a layer in which the plurality of convex portions is arranged has higher smoothness as compared to a surface of the plurality of convex portions.

15. The method according to claim 12, wherein
in the forming of the plurality of convex portions, after an amorphous silicon layer is formed on an inner surface of the trench, a Si nucleation process and a heat treatment are performed.

16. The method according to claim 12, wherein
the dielectric is formed of either Al₂O₃ or silicon dioxide as a main component.

17. The method according to claim 12, wherein
the plurality of convex portions formed includes at least one hemispherical convex portion or at least one mushroom-shaped convex portion.

18. The method according to claim 12, wherein
the plurality of convex portions is irregularly arranged along an inner surface of the trench.
